(19) United States
(12) Patent Application Publication
(10) Pub. No.: US 2007/0148972 A1
(43) Pub. Date: Jun. 28, 2007

(54) Method of repairing seed layer for damascene interconnects

(76) Inventors: Kenichi Hara, Nirasaki-Shi (JP); Mitsuaki Iwashita, Nirasaki-Shi (JP); Hidetami Yaegashi, Tokyo-To (JP)

Correspondence Address: Smith, Gambrell & Russell, Suite 800, 1850 M Street, N.W., Washington, DC, 20036, US

(21) Appl. No.: 11/643,959

(22) Filed: Dec. 22, 2006

(30) Foreign Application Priority Data
Dec. 26, 2005 (JP) 2005-371893

(51) Int. Cl. H01L 21/44

(52) U.S. Cl. 438/687

(57) ABSTRACT

Disclosed is a method of repairing, before embedding a recess with copper, defects of a seed layer formed by sputtering, when forming damascene interconnects. After a copper (silver is also available) nanoparticle-containing sol, e.g., a copper ink is applied onto a substrate, an etch back process for removing the excessive copper ink is performed by supplying an organic solvent onto the substrate. Thereafter, a disperse medium in the copper ink is evaporated by a baking process; and then a dispersant in the copper ink is removed and the nanoparticles are combined with each other to provide a continuous copper film by an annealing process. The etch back process prevents development of defects in a repaired seed layer.

### FIELD OF THE INVENTION

The present invention relates to a technique for repairing a seed layer which is formed before embedding of a wiring material in a damascene process.

### BACKGROUND ART

In order to cope with a demand for a higher integration and higher capacity of a semiconductor device, a copper (Cu) wiring of a lower electric resistivity has been increasingly employed in place of a conventional aluminium (Al) wiring. Since it is difficult to form a copper wiring pattern by a dry etching process, a damascene process, that embeds a groove formed in a surface of a substrate with a wiring material thereby to form a copper wiring pattern, is preferably used.

A copper wiring technique by a damascene process is known per se by JP2002-118109A, for example, which will be briefly described with reference to FIG. 11. At first, in a multilayered wiring substrate 200, an insulating film 200d is formed on an insulating substrate 200c having a copper wiring 200b formed therein. Then, a groove 200a is formed in the insulating film 200d at a position above the copper wiring 200b. A tantalum-series barrier metal 201 is formed on the inner wall surface of the groove 200a by sputtering (see, FIG. 11(a)). Next, a copper seed layer 202 is formed on the surface of the barrier metal film 201 by sputtering (see, FIG. 11(b)). Then, electroplating process grows copper in the groove 200a to embed the groove with a copper plating 203 (see, FIG. 11(c)). Thereafter, the excessive wiring material outside the groove 200a is removed by CMP (chemical mechanical polishing) (see, FIG. 11(d)).

The foregoing tantalum-series barrier metal film and the copper seed layer are formed by a sputtering technique called iPVD (ion physical vapor deposition). If miniaturization of wiring pattern further progresses, it is expected that the coverage of the barrier metal film and the copper seed layer is degraded. For example, as shown in FIG. 12(a), portions not covered with the copper seed layer or portions 204 having a small thickness of copper seed layer 202 may possibly appear near the bottom of the groove (i.e., trench). If such defects exist in the copper seed layer 202, an unstable growth of a copper film during succeeding electroplating process may possibly occur, or peeling-off of the seed layer may possibly occur. Moreover, if the coverage of the copper seed layer 202 is insufficient, it is possible that the plating current does not flow sufficiently, and consequently, defects such as voids (gaps) 205 or seams 206 may be developed in the copper plating 203, as shown in FIG. 12(b). These defects may cause a failure of a circuit such as a disconnection.

### DISCLOSURE OF THE INVENTION

The present invention was made in view of the above circumstances, and the main object of the present invention is to provide a technique for repairing a seed layer of a low coverage. A further object of the present invention is, by providing a seed layer of a high coverage, to allow a wiring material to stably grow on the seed layer by electroplating or CVD (chemical vapor deposition), so as to provide damascene interconnects free of defects such as voids.

In order to achieve the above objectives, the present invention provides a method of repairing defects in a seed layer formed of a metallic wiring material, the seed layer being formed in a groove formed on a substrate, the method including the steps of: (a) supplying a nanoparticle-containing sol containing nanoparticles of a metallic wiring material onto the seed layer, thereby forming a nanoparticle-containing coating film; (b) supplying, after the step (a), an organic solvent onto the nanoparticle-containing coating film, thereby etching-back the nanoparticle-containing coating film; and (c) heating, after the step (b), the substrate at a first temperature, thereby combining the nanoparticles contained in the nanoparticle-containing coating film to form a continuous metallic film.

In a preferred embodiment, the method further includes the step of (d) exposing, after the step (b) and before the step (c), the substrate to an atmosphere of a temperature lower than the first temperature, thereby removing at least a disperse medium of the nanoparticle-containing sol contained in the nanoparticle-containing coating film and the organic solvent used in the step (b) from the nanoparticle-containing coating film.

In a preferred embodiment, the method further includes the steps of: (e) exposing, after the step (a) and before the step (b), the substrate to an atmosphere of a temperature lower than the first temperature, thereby removing at least a disperse medium of the nanoparticle-containing sol contained in the nanoparticle-containing coating film from the nanoparticle-containing coating film; and (f) exposing, after the step (b) and before the step (c), the substrate to an atmosphere of a temperature lower than the first temperature, thereby removing at least the organic solvent used in the step (b) from the nanoparticle-containing coating film.

The present invention further provides a method of forming damascene interconnects including the steps of: preparing a substrate having an insulating film in which a groove is formed; forming a seed layer, formed of a metallic wiring material, on an inner surface of the groove by sputtering; repairing defects of the seed layer by the above-described repairing method; and embedding the groove with a wiring material by electroplating or CVD after repairing the seed layer.

### BRIEF DESCRIPTION OF THE DRAWINGS

FIG. 1 is a flowchart for explaining formation of damascene interconnects;

FIG. 2 shows cross-sectional views showing the statuses of a substrate corresponding to some of the steps in the flowchart of FIG. 1;

FIG. 3 shows cross-sectional views showing the statuses of the substrate corresponding to some of the steps in the flowchart of FIG. 1;

FIG. 4 is a flowchart for explaining seed repair;

FIG. 5 shows cross-sectional views showing the statuses of the substrate corresponding to some of the steps in the flowchart of FIG. 1;

FIG. 6 shows cross-sectional views showing the statuses of the substrate corresponding to some of the steps in the flowchart of FIG. 1;

FIG. 7 shows an SEM photograph of a section of a substrate, showing a state of a seed layer before seed repair;

FIG. 8 shows SEM photographs of a section of a substrate, showing changes in the status of the seed layer according to seed repair of Example 1, wherein (a) shows after baking and (b) shows after annealing;

FIG. 9 shows SEM photographs of a section of a substrate, showing changes in the status of the seed layer according to seed repair of Comparative Example, wherein (a) shows after baking and (b) shows after annealing;

FIG. 10 shows SEM photographs of a section of a substrate, showing changes in the status of the seed layer according to seed repair of Example 2, wherein (a) shows after baking and (b) shows after annealing;

FIG. 11 is a flowchart for explaining formation of damascene interconnects; and

FIG. 12 is a cross-sectional for explaining defects developed in an embedded wiring layer due to defects of a seed layer.

### DESCRIPTION OF THE PREFERRED EMBODIMENTS

Preferred embodiments of the present invention will be described herebelow with reference to the accompanying drawings.

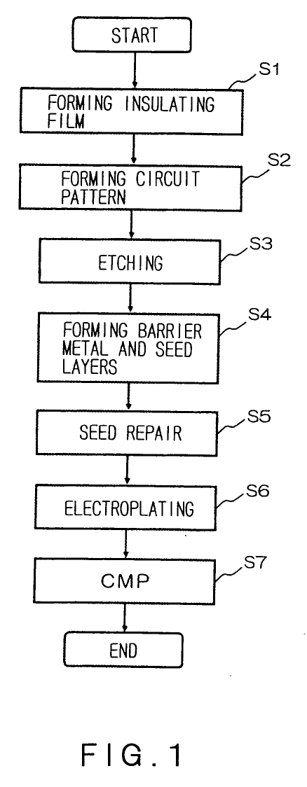

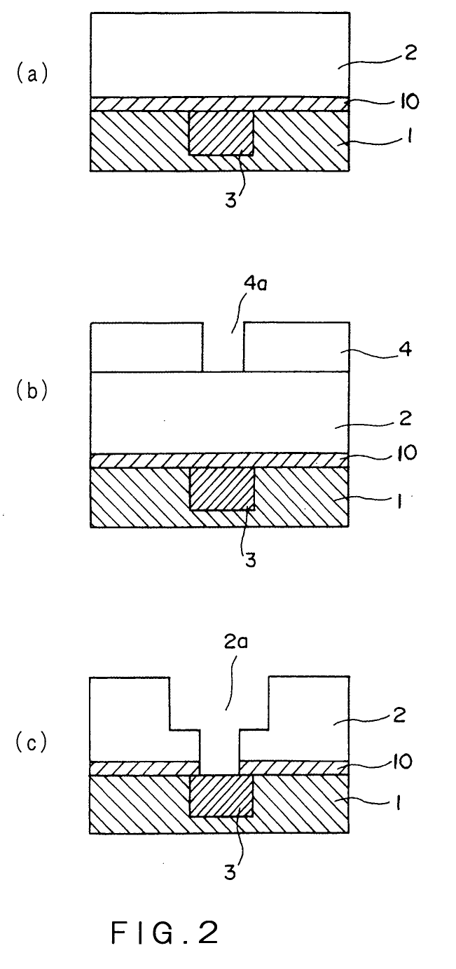

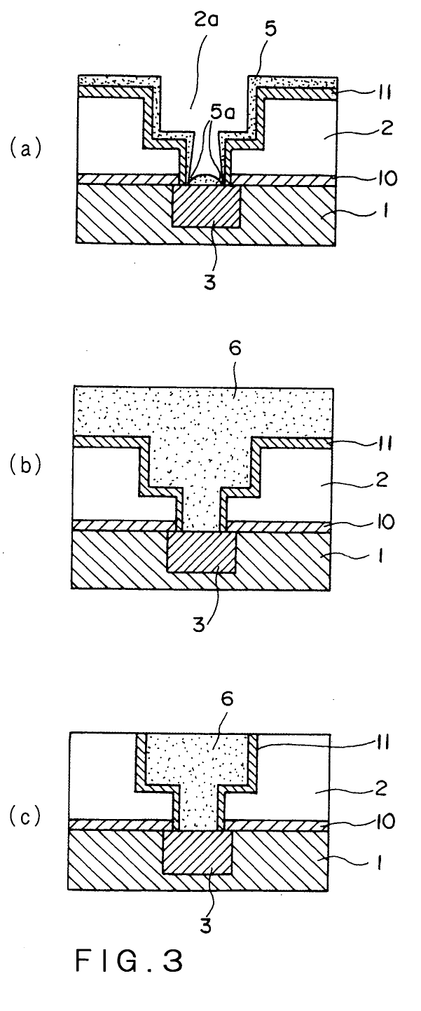

At first, a damascene wiring method is described with reference to a flowchart of FIG. 1, and FIGS. 2 and 3 showing cross-sectional views of a substrate corresponding to some of the steps in the flowchart of FIG. 1.

At first, as shown FIG. 2(a), an etch stop layer 10 is formed on a semiconductor substrate 1 (hereafter referred to as “substrate 1”), and an insulating film 2 (silicon oxide film, for example) is grown on the etch stop layer 10 (step S1 in FIG. 1). Then, a photoresist 4 is applied onto the insulating film 2 and the photoresist 4 is exposed and developed, thereby to form a pattern 4a corresponding to an arrangement pattern of via holes and trenches to be formed, as shown in FIG. 2(b) (step S2 in FIG. 1). In the illustrated embodiment, the pattern 4a is formed above a copper wiring 3 which has been already formed in the substrate 1. Next, the insulating film 2 is etched by using, as a mask, the pattern 4a formed in the step S2, thereby to form recesses 2a such as via holes and trenches corresponding to the circuit pattern, as shown in FIG. 2(c) (step S3 in FIG. 1). Here, the insulating film 2 is etched twice by using the patterns 4a different in width, whereby a stepped recess 2a is formed.

Then, as shown in FIG. 3(a), a barrier metal film 11 for preventing diffusion of copper (Cu), or a wiring material, is formed on an inner wall surface of the recess 2a (and a surface of the insulating film 2) by sputtering. Further, a copper seed layer 5 is deposited on the barrier metal film 11 by sputtering (step S4 in FIG. 1). As shown in FIG. 3(a), near the bottom of the recess 2a, the copper seed layer 5 has defects, i.e., portions which are not covered with the copper seed layer 5, or portions 5a where the thickness of the copper seed layer 5 is small. Seed repair according to the present invention is performed for repairing the copper seed layer 5 of poor coverage (step S5 in FIG. 1). The seed repair will be described in detail later.

After the seed repair, as shown in FIG. 3(b), the recess 2a of the circuit pattern is embedded with a copper plating layer 6 by electroplating (step S6 in FIG. 1). Then, by CMP, the excessive copper plating layer 6 is removed and a flattening process is performed as shown in FIG. 3(c) (step S7 in FIG. 1). According to these steps, the damascene interconnects are formed. The copper layer designated by reference numeral 6 may be formed by CVD.

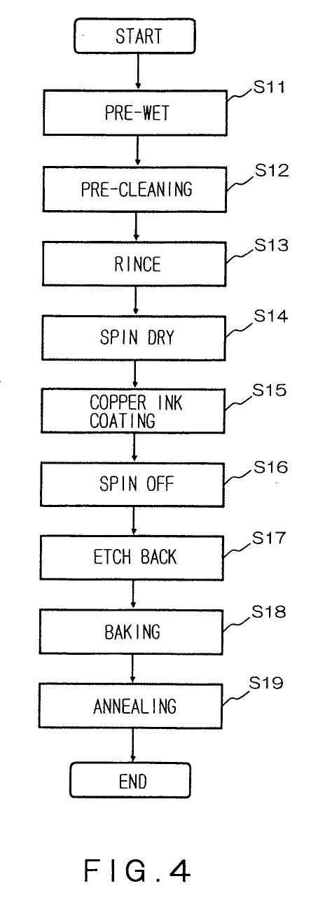

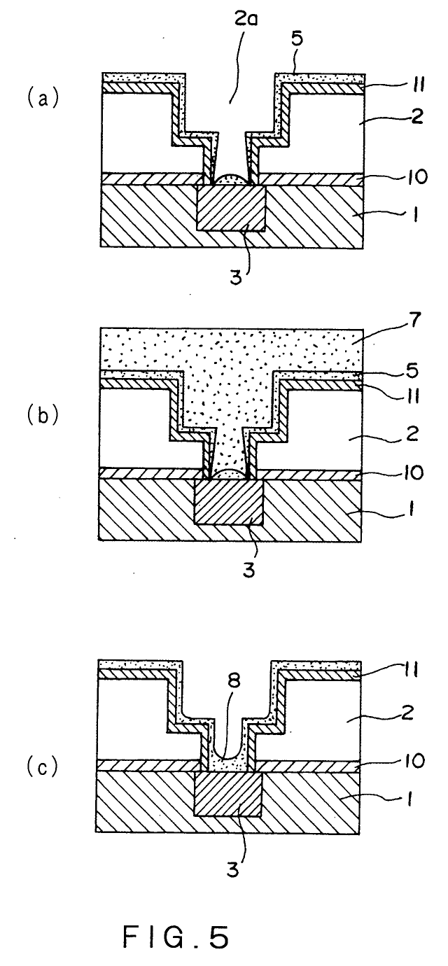

Next, the seed repair performed in the step S5 in FIG. 1 is described in detail, with reference to the flowchart of FIG. 4, and FIG. 5 showing cross-sectional views of the substrate corresponding to some of the steps in the flowchart of FIG. 4. The respective steps S11 to S17 for the seed repair are performed by using a so-called spin coater (not shown). Since a spin coater is well known per se to those skilled in the art of semiconductor manufacturing, the structure thereof is not described herein. In the steps S11 to S17, the substrate 1 is held by a spin chuck (not shown) capable of rotating about a vertical axis at a controlled rotational speed, with the lower surface of the substrate 1 being held by suction, or the circumference thereof being mechanically held; and various process liquids are supplied to the substrate 1 on demand from process liquid supplying nozzles (not shown).

As shown in FIG. 5(a), for the purpose of improved wettability, in other words, for the purpose of allowing a chemical liquid to pervade the recess 2a in the following step S12, a pre-wet process is performed by using deionized water (step S 11 in FIG. 4). The pre-wet process is performed by supplying deionized water through a nozzle onto the copper seed layer 5 from above the center part of the substrate 1, while rotating the substrate 1 at a rotational speed in the range of 0 to 300 rpm. In order to enhance the efficiency of the pre-wet process, the deionized water may be supplied to the substrate 1 while the nozzle is scanning the substrate 1.

Then, a pre-cleaning process is performed for removing copper oxide on a surface of the copper seed layer 5 (step S12 in FIG. 4), by supplying an organic acid solution, preferably an acid solution containing a carboxyl such as oxalic acid, onto the copper seed layer 5 from above the substrate 1, while rotating the substrate 1 at a rotational speed in the range of 0 to 1,000 rpm.

After the pre-cleaning process, a rinse process (step S13 in FIG. 4) is performed by supplying deionized water through a nozzle onto the copper seed layer 5 from above the substrate 1, while rotating the substrate 1 at a rotational speed in a range of 0 to 1,000 rpm. Following thereto, a spin dry process is performed (step S14 in FIG. 4) to the substrate, by rotating the substrate 1 at a high rotational speed in the range of 300 to 1,500 rpm.

Then, as shown in FIG. 5(b), a copper ink coating process is performed by applying a copper nanoparticle-containing sol 7 (hereafter referred to as “copper ink 7”) onto the copper seed layer 5 to form thereon a copper nanoparticle-containing coating film (hereafter referred to as “copper ink film”) (step S15 in FIG. 4). This coating process (step S15 in FIG. 4) is performed by a spin coating method that supplies the copper ink 7 through a nozzle onto the copper seed layer 5 from above the substrate 1 while the substrate 1 is rotated at a rotational speed in a range of 0 to 300 rpm. Alternatively, the copper ink 7 may be applied onto the substrate 1 by a scan coating method without rotating the substrate 1. An ink containing copper or other nanoparticles of a metal for wiring which is used herein may be a conductive ink commercially available from, for example, ULVAC Materials, Inc. (Japan), but is not limited thereto.

Subsequently, the supply of the copper ink 7 is stopped and the rotational speed of the substrate 1 is increased up to 100 to 1,500 rpm so as to perform a spin-off process that removes excessive copper ink on the substrate 1, and thereby, in-plane uniformity of the thickness of the copper ink film on the substrate 1 is also improved (step S16 in FIG. 4).

Next, the excessive copper ink film is removed by supplying an organic solvent through a nozzle onto the copper ink film from above the substrate 1, while rotating the substrate 1 at a rotational speed in the range of 0 to 300 rpm (step S17 in FIG. 4). Thus, the copper ink film of a large thickness formed above the entrance of the recess 2a is removed, and etch back of the copper ink film is performed. The organic solvent used herein is preferably the same as the disperse medium contained in the copper ink 7, i.e., the nanoparticle-containing sol. However, the organic solvent is not limited to one that is identical to the disperse medium. Any type of organic solvent may be used as the organic solvent, as long as it is compatible with the disperse medium contained in the copper ink, and fulfills the same function as described above, without causing any adverse effect on components of the copper ink 7. For example, toluene may be used as the organic solvent. Another usable organic solvent is ether, for example.

Thereafter, a baking process is performed by heating the substrate 1 in an atmosphere of an inert gas, in particular, nitrogen (N₂) or argon (Ar), at a temperature in the range of 50° C. to 250° C., for a time period in the range of 0 to 10 minutes. The baking process may be performed in air atmosphere (it is the same with the other baking processes). Thereby, the disperse medium contained in the copper ink film and the organic solvent which was supplied in the step S17 are evaporated (step S18 in FIG. 4).

Then, an annealing process is performed by heating the substrate 1 in an atmosphere of an inert gas, in particular, nitrogen (N₂) or argon (Ar), at a temperature in the range of 100° C. to 1,000° C. which is higher than that in the step S17, for a time period in the range of 0 to 30 minutes (step S19 in FIG. 4). Thereby, a dispersant of copper nanoparticles (which is an antiaggregating component or an encapsulant contained in the copper ink) is burned off, or removed, and the copper nanoparticles are sintered or melted to be combined with each other so that a continuous copper film is formed. Due to the foregoing series of steps, the defective seed layer 5 is repaired to have a conformal shape and to be a seed layer of excellent coverage (coverage layer 8), as shown in FIG. 5(c).

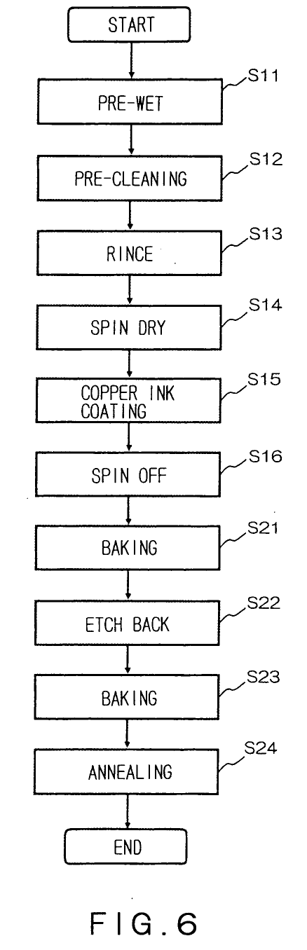

In the flowchart of FIG. 4, the etch back process that applies the organic solvent is performed before the baking process, however, the etch back process may be performed after the baking process. A series of steps performed in this latter case are shown in the flowchart of FIG. 6, which, as can be seen therefrom, is identical to the flowchart of FIG. 4 as for the steps until the copper ink 7 spin-off process (step S16 of FIG. 6).

After the process of spin-off of the copper nanoparticle-containing solution, a baking process is performed by heating the substrate 1 in an atmosphere of an inert gas, in particular, nitrogen (N₂) or argon (Ar), at a temperature in the range of 50° C. to 250° C., for a time period in the range of 0 to 10 minutes (step S21 in FIG. 6). Thereby, a disperse medium in the applied copper ink film is evaporated, and the copper ink film is solidified to be fixed on the seed layer 5.

After the baking process, an organic solvent (e.g., toluene) is supplied onto the copper ink film while the substrate 1 is rotated, thereby the excessive copper ink film of a large thickness formed above the entrance of the recess 2a is removed, and etch back of the copper ink film is performed (step S22 in FIG. 6).

Then, a baking process is performed for evaporating the organic solvent supplied in the step S22 to remove the same, by heating the substrate 1 in an atmosphere of an inert gas, in particular, nitrogen (N₂) or argon (Ar), at a temperature in the range of 50° C. to 250° C., for a time period in the range of 0 to 10 minutes (step S23 in FIG. 6).

At last, an annealing process is performed for removing a dispersant contained in the copper ink film and for combining the nanoparticles with each other to obtain a continuous film, by heating the substrate 1 in an atmosphere of an inert gas, in particular, nitrogen (N₂) or argon (Ar), at a temperature in the range of 100° C. to 1,000° C., for a time period in the range of 0 to 30 minutes (step S24 in FIG. 6). Thus, the defects in the copper seed layer are repaired, and a copper seed layer (i.e., coverage layer 8) which is repaired into a conformal shape can be obtained.

According to the embodiment shown in FIG. 6, before performing the step S22 for removing the unnecessary copper ink film and etching back the copper ink film by means of the organic solvent, the baking process (step S21) for evaporating the disperse medium contained in the applied copper ink film is performed so as to fix the copper ink film on the copper seed layer 5. Thus, uniformity of the process in the step S22 is improved, whereby a coverage layer 8 of a higher uniformity can be obtained.

According to the above embodiments, defects that are developed at portions, where film formation by iPVD is difficult, can be reliably repaired owing to the benefit of a wet process, i.e., excellent coverage. In addition, by removing the excessive copper ink by the organic solvent (see, the below examples) after the copper ink is applied, development of defects such as voids in a layer formed by the seed repair can be prevented. As a result, a conformal coverage layer (having a uniform thickness) can be obtained. Therefore, copper grows stably in the succeeding electroplating process or CVD process, and thus interconnects free of defects such as voids can be obtained.

When removal (etch back) of excessive copper ink film is performed by means of an organic solvent, it is most preferable to remove all the copper ink other than the copper ink on portions to be repaired (the bottom of a recess, in particular, near the corner portions). When the inner surface of a recess is stepped as in the illustrated embodiment, a copper ink film also remains at corner portions of the stepped part (i.e., the bottom of the trench), but it arises no problem. The situation where the whole interior space of the recess is filled with copper ink should be avoided after the etch back process. Under such a situation, proper seed repair can not be achieved, as will be seen from the examples described later. Thus, after the etch back process, it is preferable that, except for the bottom of the recess, no copper ink remains at the center region of the recess with respect to its width direction in its cross section. When a copper ink film embedded in a recess having a step as illustrated is subjected to a proper etch back process, the copper ink has a V-shaped or U-shaped region at the center part of the recess in its width direction from which the copper ink is removed.

In the above embodiments, although copper (Cu) is used as a wiring material, silver (Ag) of a lower resistivity may be used. In this case, the atmosphere for the baking process and the annealing process may either be of the aforementioned inert gas such as nitrogen (N₂) or argon (Ar), however, alternatively, the atmosphere may be of a mixed gas prepared by adding oxygen (O₂) to the inert gas. Addition of oxygen is particularly effective in removing a dispersant contained in a silver nanoparticle-containing sol.

### EXAMPLES

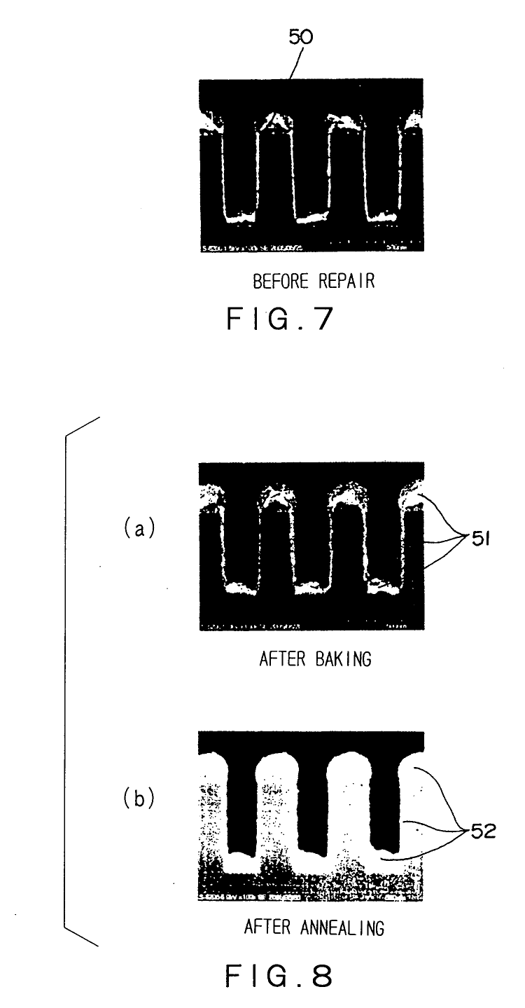

Next, results of experiments conducted for verifying effects, in particular, effects of the etch back process according to the present invention, will be described. Each of the photographs shown in FIGS. 7 to 10 is a secondary electron image (SEI) of a section of a substrate taken by a scanning electron microscope (SEM). In these photographs, parts made of copper look white.

### Example 1

In Example 1, seed repair was carried out in accordance with the steps shown in the flowchart of FIG. 4. In Example 1, a copper layer 50 having poor coverage shown in FIG. 7 was subjected to the seed repair according to the steps of the flowchart of FIG. 4. In Example 1, an etch back process by means of an organic solvent was performed after application of a copper ink and before a baking process for fixing the copper ink. To be specific, the seed repair was carried out according to the procedures described below. A pre-wet process was first performed by supplying deionized water onto a substrate for five seconds; then a pre-cleaning process was performed by supplying a malic acid solution onto the substrate for twenty seconds; then a rinse process was performed by supplying deionized water for ten seconds; and then a spin dry process was performed by rotating the substrate at 1,300 rpm for twenty seconds. Then, a copper ink was applied onto the substrate without rotating the substrate (copper ink coating process); and then the excessive copper ink was removed by rotating the substrate at 1,300 rpm for 100 seconds (spin-off process). Then, before the copper ink dried, an etch back process was performed by supplying toluene onto the substrate while rotating the substrate at 100 rpm. Then, a baking process was performed at 100° C. for three minutes (here, air atmosphere was used), and an annealing process was performed at 400° C. in nitrogen gas atmosphere.

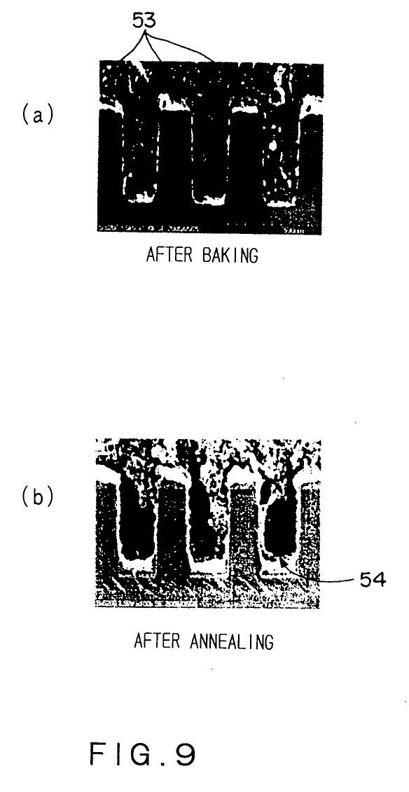

FIG. 8 (a) and FIG. 8 (b) show the statuses of the substrate in Example 1 after the baking process and after the annealing process, respectively; and FIG. 9 (a) and FIG. 9 (b) show the statuses of the substrate in Comparative Example after the baking process and after the annealing process, respectively. Comparative Example differs from Example 1 only in that the etch back process (step S17), of the steps shown in the flowchart of FIG. 4, was not performed.

With Example 1 in which the etch back process was performed: as shown in FIG. 8(a), after the baking process, the copper ink (see, reference numeral 51) was well fixed on portions near the bottom and the sidewall of the groove; and as shown in FIG. 8(b), after the annealing process, a copper seed layer 52, i.e., coverage layer, which had been repaired to be conformal, was obtained.

On the other hand, with Comparative Example in which the etch back process was not performed: as shown in FIG. 9(a), after the baking process, a copper ink film 53 completely blocked the entrance of a recess; and as shown in FIG. 9(b), after the annealing process, a film including voids 54 (spaces looking black) was formed. As apparent from above, the copper ink is not suited for filling a recess, but is suitably used for the seed repair on condition that the etch back process is properly performed.

### Example 2

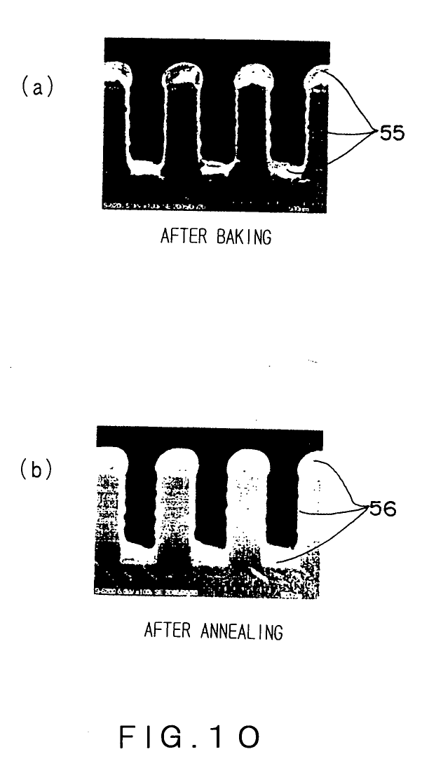

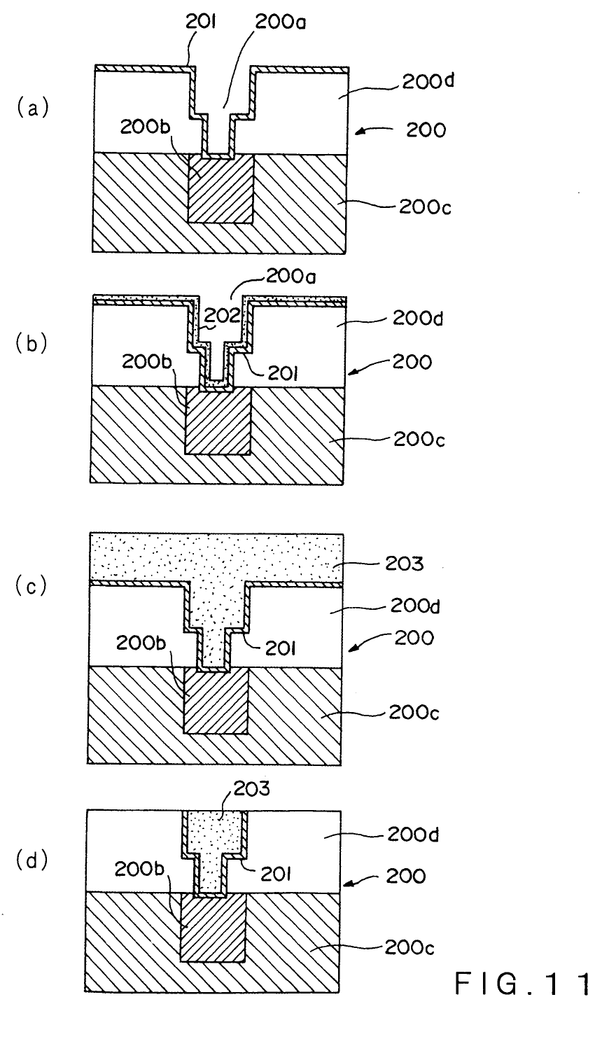

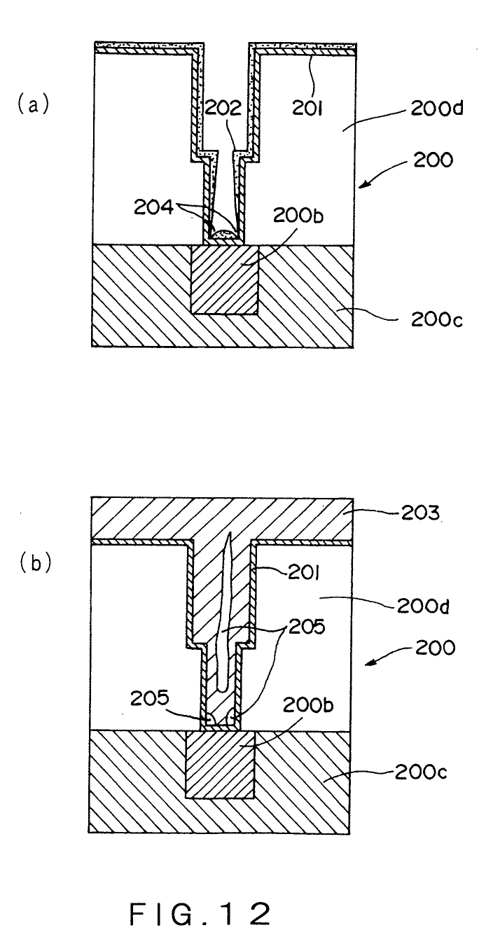

In Example 2, seed repair was carried out in accordance with the steps shown in the flowchart of FIG. 6. In Example 2, a baking process for fixing a copper ink was performed after application of the copper ink; and thereafter an etch back process by means of an organic solvent was performed. Conditions of the respective steps were substantially the same as those in Example 1. FIG. 10 (a) and FIG. 10 (b) show the statuses of the substrate in Example 1 after the baking process and after the annealing process, respectively. The result of Example 2 was similar to that of Example 1, that is, as shown in FIG. 10(a), after the baking process, the copper ink (see, reference numeral 55) was well fixed on portions near the bottom of the groove and the sidewall of the groove. As shown in FIG. 10(b), after the annealing process, a copper seed layer 56, i.e., coverage layer, which had been repaired to be conformal, was obtained.

As is apparent from Examples 1 and 2, it was found that, according to the method of the present invention, a defective seed layer on portions near the bottom of the recess and on the sidewall of the recess could be satisfactorily repaired.

1. A method of repairing defects in a seed layer formed of a metallic wiring material, the seed layer being formed in a groove formed on a substrate, said method comprising the steps of:
(a) supplying a nanoparticle-containing sol containing nanoparticles of a metallic wiring material onto the seed layer, thereby forming a nanoparticle-containing coating film;
(b) supplying, after the step (a), an organic solvent onto the nanoparticle-containing coating film, thereby etching-back the nanoparticle-containing coating film; and
(c) heating, after the step (b), the substrate at a first temperature, thereby combining the nanoparticles contained in the nanoparticle-containing coating film to form a continuous metallic film.

2. The method according to claim 1 further comprising the step of:
(d) exposing, after the step (b) and before the step (c), the substrate to an atmosphere of a temperature lower than the first temperature, thereby removing at least a disperse medium of the nanoparticle-containing sol contained in the nanoparticle-containing coating film and the organic solvent used in the step (b) from the nanoparticle-containing coating film.

3. The method according to claim 1 further comprising the steps of:
(e) exposing, after the step (a) and before the step (b), the substrate to an atmosphere of a temperature lower than the first temperature, thereby removing at least a disperse medium of the nanoparticle-containing sol contained in the nanoparticle-containing coating film from the nanoparticle-containing coating film; and
(f) exposing, after the step (b) and before the step (c), the substrate to an atmosphere of a temperature lower than the first temperature, thereby removing at least the organic solvent used in the step (b) from the nanoparticle-containing coating film.

4. The method according to claim 1, wherein the organic solvent used in the step (b) is toluene.

5. The method according to claim 1, wherein the wiring material is copper (Cu) or silver (Ag).

6. A method of forming damascene interconnects comprising the steps of:
preparing a substrate having an insulating film in which a groove is formed;
forming a seed layer, formed of a metallic wiring material, on an inner surface of the groove by sputtering;
repairing defects of the seed layer; and
embedding the groove with a wiring material by electroplating or CVD after repairing the seed layer;
wherein the step of repairing defects of the seed layer includes the steps of:
(a) supplying a nanoparticle-containing sol containing nanoparticles of a metallic wiring material onto the seed layer, thereby forming a nanoparticle-containing coating film;
(b) supplying, after the step (a), an organic solvent onto the nanoparticle-containing coating film, thereby etching-back the nanoparticle-containing coating film; and
(c) heating, after the step (b), the substrate at a first temperature, thereby combining the nanoparticles contained in the nanoparticle-containing coating film to form a continuous metallic film.
